(19) United States
(12) Patent Application Publication
(10) Pub. No.: US 2007/0145453 A1
(43) Pub. Date: Jun. 28, 2007

(54) Dielectric layer for electronic devices

(75) Inventors: Yiliang Wu, Mississauga (CA); Beng S. Ong, Mississauga (CA)

Correspondence Address: Richard M. Klein;FAY, SHARPE, FAGAN, MINNICH & McKEE, LLP, SEVENTH FLOOR, 1100 SUPERIOR AVENUE, CLEVELAND, OH, 44114-2579, US

(73) Assignee: XEROX CORPORATION

(21) Appl. No.: 11/318,044

(22) Filed: Dec. 23, 2005

(51) Int. Cl. H01L 29/94

(52) U.S. Cl. 257/310; 257/E21.409

(57) ABSTRACT

A dielectric layer for electronic devices is disclosed herein. The dielectric layer comprises inorganic nanoparticles dispersed in a polymer selected from the group consisting of polysiloxane, polysilsesquioxane, and mixtures thereof. The layer improves the carrier mobility and current on/off ratio of an electronic device incorporating it, especially a thin film transistor.

### STATEMENT REGARDING FEDERALLY SPONSORED RESEARCH

This development was made with United States Government support under Cooperative Agreement No. 70NANBOH3033 awarded by the National Institute of Standards and Technology (NIST). The United States Government has certain rights in the development.

### CROSS-REFERENCE TO RELATED APPLICATIONS

This application relates to U.S. patent application Ser. No. ______ [20050945-US-NP, XERZ 201132], filed , and to U.S. patent application Ser. No. ______[20050659-US-NP, XERZ 201173], filed ______; these disclosures are hereby incorporated by reference in their entirety.

### BACKGROUND

The present disclosure relates, in various embodiments, to compositions suitable for use in electronic devices, such as thin film transistors (“TFT”s). The present disclosure also relates to layers produced using such compositions and electronic devices containing such layers.

Thin film transistors (TFTs) are fundamental components in modern-age electronics, including, for example, sensors, image scanners, and electronic display devices. TFT circuits using current mainstream silicon technology may be too costly for some applications, particularly for large-area electronic devices such as backplane switching circuits for displays (e.g., active matrix liquid crystal monitors or televisions) where high switching speeds are not essential. The high costs of silicon-based TFT circuits are primarily due to the use of capital-intensive silicon manufacturing facilities as well as complex high-temperature, high-vacuum photolithographic fabrication processes under strictly controlled environments. It is generally desired to make TFTs which have not only much lower manufacturing costs, but also appealing mechanical properties such as being physically compact, lightweight, and flexible.

TFTs are generally composed of a supporting substrate, three electrically conductive electrodes (gate, source and drain electrodes), a channel semiconductor layer, and an electrically insulating gate dielectric layer separating the gate electrode from the semiconductor. The channel semiconductor is in turn in contact with the source and drain electrodes. Recently, there has been an increased interest in plastic thin film transistors which can potentially be fabricated using solution-based patterning and deposition techniques, such as spin coating, solution casting, dip coating, stencil/screen printing, flexography, gravure, offset printing, ink jet-printing, micro-contact printing, and the like, or a combination of these processes. Such processes are generally simpler and more cost effective compared to the complex photolithographic processes used in fabricating silicon-based thin film transistor circuits for electronic devices. To enable the use of these solution-based processes in fabricating thin film transistor circuits, solution processable materials are therefore required.

Most of the current materials research and development activities for plastic thin film transistors has been devoted to semiconductor materials, particularly solution-processable organic and polymer semiconductors. On the other hand, other material components such as solution processable dielectric materials have not been receiving much attention.

For plastic thin film transistor applications, it is desirable to have all the materials be solution processable. It is also highly advantageous that the materials be fabricated on plastic substrates at a temperature of less than about 200° C., and particularly less than about 150° C. The use of plastic substrates, together with flexible organic or polymer transistor components can transform the traditional thin film transistor circuits on rigid substrates into mechanically more durable and structurally flexible plastic thin film transistor circuit designs. Flexible thin film transistor circuits will be useful in fabricating mechanically robust and flexible electronic devices.

Other than solution processable semiconductor and conductor components, solution processable dielectric materials are critical components for the fabrication of plastic thin film transistor circuits for use in plastic electronics, particularly flexible large-area plastic electronics devices.

The dielectric layer should be free of pinholes and possess low surface roughness (or high surface smoothness), a high dielectric constant, a high breakdown voltage, adhere well to the gate electrode, and offer other functionality. It should also be compatible with semiconductor materials because the interface between the dielectric layer and the organic semiconductor layer critically affects the performance of the TFT. Additionally, for flexible integrated circuits on plastic substrates, the dielectric layer should be prepared at temperatures that would not adversely affect the dimensional stability of the plastic substrates, i.e., generally less than about 200° C., including less than about 150° C.

A wide variety of organic and polymer materials, including polyimides [Z. Bao, et al. J. Chem. Mater. 1997, Vol. 9, pp 1299.], poly(vinylphenol) [M. Halik, et al. J. AppL. Phys. 2003, Vol. 93, pp 2977.], poly(methyl methacrylate) [J. Ficker, et. al. J. Appl. Phys. 2003, Vol. 94, 2638.], polyvinylalcohol [R. Schroeder, et. al. Appl. Phys. Leff. 2003, Vol. 83, pp 3201.], poly(perfuoroethylene-co-butenyl vinyl ether) [J. Veres, et al. Adv. Funct. Mater. 2003, Vol. 13, pp 199.]], and benzocyclobutene [L.-L. Chua, et. al. Appl. Phys. Leff. 2004, Vol. 84, 3400.], have been studied as dielectric layers. These materials, however, do not generally meet all the economic and/or functional requirements of low-cost thin film transistors.

Therefore, it is desirable to provide a dielectric material composition that is solution processable and which composition can be used in fabricating the gate dielectric layers of thin film transistors. It is further desirable to provide a dielectric material that will permit easy fabrication of a gate dielectric layer for thin film transistors by solution processes, that is pinhole free, has a high dielectric constant, and exhibits electrical and mechanical properties that meet the device physical and performance requirements. It is also desirable to provide a material for fabricating the dielectric layerforthin film transistors that can be processed at a temperature compatible with plastic substrate materials to enable fabrication of flexible thin film transistor circuits on plastic films or sheets.

### BRIEF DESCRIPTION

The present disclosure is directed, in various embodiments, to an electronic device having a dielectric layer. The dielectric layer comprises a polymer selected from the group consisting of polysiloxane, polysilsesquioxane, and mixtures thereof. The layer further comprises inorganic particles.

A process for fabricating an electronic device having the dielectric layer described above is also disclosed. In particular, the electronic device is a thin film transistor.

These and other non-limiting characteristics of the exemplary embodiments of the present disclosure are more particularly described below.

### BRIEF DESCRIPTION OF THE DRAWINGS

The following is a brief description of the drawings, which are presented for the purpose of illustrating the exemplary embodiments disclosed herein and not for the purpose of limiting the same.

FIG. 1 is a first exemplary embodiment of a TFT having a dielectric layer according to the present disclosure.

FIG. 2 is a second exemplary embodiment of a TFT having a dielectric layer according to the present disclosure.

FIG. 3 is a third exemplary embodiment of a TFT having a dielectric layer according to the present disclosure.

FIG. 4 is a fourth exemplary embodiment of a TFT having a dielectric layer according to the present disclosure.

FIG. 5 is a graph showing the typical output and transfer curves of the thin film transistors of one embodiment of the present disclosure.

### DETAILED DESCRIPTION

A more complete understanding of the components, processes, and apparatuses disclosed herein can be obtained by reference to the accompanying figures. These figures are merely schematic representations based on convenience and the ease of demonstrating the present development and are, therefore, not intended to indicate relative size and dimensions of the devices or components thereof and/or to define or limit the scope of the exemplary embodiments.

Although specific terms are used in the following description for the sake of clarity, these terms are intended to refer only to the particular structure of the embodiments selected for illustration in the drawings and are not intended to define or limit the scope of the disclosure. In the drawings and the following description below, it is to be understood that like numeric designations refer to components of like function.

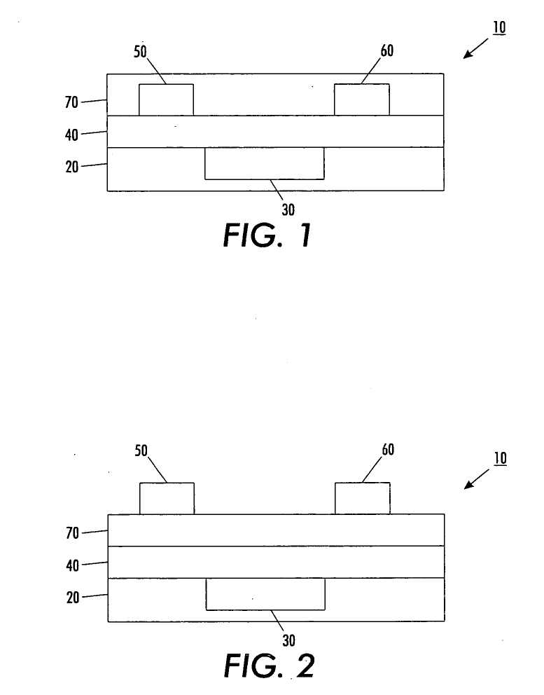

FIG. 1 illustrates a first TFT configuration. This TFT has a bottom-gate configuration. The TFT 10 comprises a substrate 20 in contact with the gate electrode 30 and a dielectric layer 40. Although here the gate electrode 30 is depicted within the substrate 20, this is not required; the key is that the dielectric layer 40 separates the gate electrode 30 from the source electrode 50, drain electrode 60, and the semiconductor layer. 70. The source electrode 50 contacts the semiconductor layer 70. The drain electrode 60 also contacts the semiconductor layer 70.

FIG. 2 illustrates a second TFT configuration. The TFT 10 comprises a substrate 20 in contact with the gate electrode 30 and a dielectric layer 40. The semiconductor layer 70 is placed on top of the dielectric layer 40 and separates it from the source and drain electrodes 50 and 60.

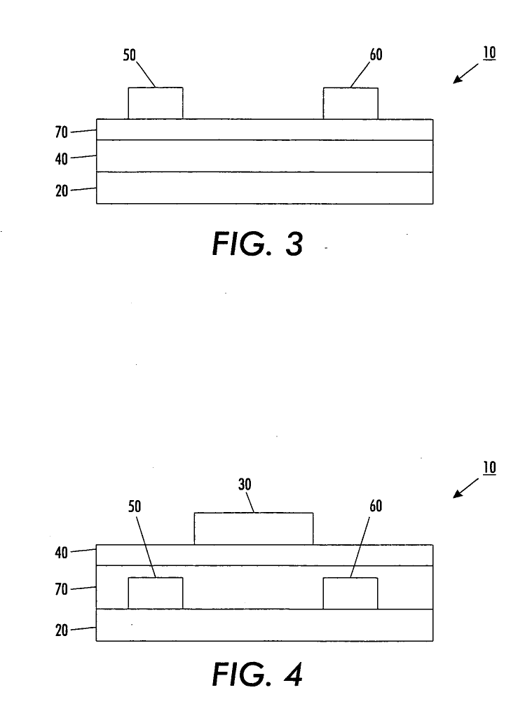

FIG. 3 illustrates a third TFT configuration. The TFT 10 comprises a substrate 20 which also acts as the gate electrode and is in contact with a dielectric layer 40. The semiconductor layer 70 is placed on top of the dielectric layer 40 and separates it from the source and drain electrodes 50 and 60.

FIG. 4 illustrates a fourth TFT configuration. This TFT has a top-gate configuration. The TFT 10 comprises a substrate 20 in contact with the source electrode 50, drain electrode 60, and the semiconductor layer 70. The dielectric layer 40 is on top of the semiconductor layer 70. The gate electrode 30 is on top of the dielectric layer 40 and does not contact the semiconductor layer 70.

The dielectric layer of the present disclosure comprises a polymer selected from the group consisting of polysiloxane, polysilsesquioxane, and mixtures thereof. Polysiloxanes have a chemical structure as shown in Formula (I) below: 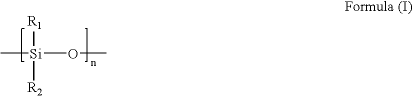
wherein R₁ and R₂ are independently selected from alkyl, alkenyl, aryl, arylalkyl, and hydrogen; wherein R₁ and R₂ may further contain a heteroatom selected from the group consisting of oxygen, sulfur, and nitrogen; and wherein n is the degree of polymerization. In one embodiment, the R₁ and R₂ are independently selected from C₁-C₄₀ aliphatic, C₄-C₄₀ alicyclic, C₇-C₄₀ arylalkyl, C₆-C₂₀ aryl, and a combination thereof. In embodiments, n is from about 4 to about 10,000. In further embodiments, n is from about 10 to about 5,000.

Polysilsesquioxanes have a chemical structure as shown in Formula (II) below:
(SiR)₂ₙO₃ₙ (II)
wherein the Rs, which can be the same or different from each other, are independently selected from alkyl, alkenyl, aryl, arylalkyl, and hydrogen; wherein the Rs may further contain a heteroatom selected from the group consisting of oxygen, sulfur, and nitrogen; and wherein n is the degree of polymerization. In one embodiment, the Rs are independently selected from C₁-C₄₀ aliphatic, C₄-C₄₀ alicyclic, C₇-C₄₀ arylalkyl, C₆-C₂₀ aryl, and a combination thereof. In embodiments, n is from about 2 to about 10,000. In further embodiments, n is from about 5 to about 5,000. In specific embodiments, the Rs are the same. In more specific embodiments, the polysilsesquioxane is poly(methyl silsesquioxane).

Polysiloxanes and polysilsesquioxanes have several characteristics which make them suitable for use in TFTs. They are very compatible with semiconductor materials, in particular p-type semiconductors such as polythiophenes and pentacenes. The term “compatible” refers to how well the semiconductor layer can perform electrically when it is deposited on the surface of the dielectric layer. For example, a hydrophobic surface is generally preferred for polythiophene semiconductors. Polysiloxanes and polysilsesquioxanes can also be cured at a-relatively low temperature such as below 200° C. They are also compatible with plastic materials such as MYLAR and thus suitable for use in flexible integrated circuits. Finally, they are reasonably soluble in common organic solvents and thus lend themselves to solution processes such as spin coating, stencil/screen printing, stamping, inkjet-printing, etc.

The dielectric layer of the present disclosure further comprises inorganic particles. In one embodiment, these inorganic particles are dispersed evenly throughout the polymer. In another embodiment, the inorganic particles may not be dispersed evenly throughout the polymer. Inorganic particles are required because the polymer has a low dielectric constant; thus, the inorganic particles chosen should have a high dielectric constant so the dielectric layer has a high dielectric constant as well. In specific embodiments, the dielectric layer comprises inorganic particles selected from the group consisting of Al₂O₃, TiO₂, ZrO₂, La₂O₃, Y₂O_{3, Ta}₂O₅, ZrSiO₄, Si₃N₄, SrO, MgO, CaO, HfSiO₄, BaTiO₃, HfO₂, and mixtures thereof. Particles of from about 1 nanometer (nm) to about 5 micrometers (μm) in average size are used. In further embodiments, nanoparticles of from about 1 nm to about 999 nm in average size are used. In specific embodiments, nanoparticles of from about 1 nm to about 100 nm are used. Nanoparticles are used because they aid in forming a smooth surface. The particles or nanoparticles may have any shape, such as sphere or rod.

The polymer and the inorganic particles are usually mixed together in a weight ratio (polymer:inorganic particles) of from about 1:1 to about 19:1. In specific embodiments, they are mixed together in a weight ratio of from about 4:1 to about 19:1.

The addition of inorganic particles will increase the dielectric constant of the dielectric layer. The dielectric constant of polysiloxanes or polysilsesquioxanes is generally from about 2.5 to about 3.2. The dielectric layer of the present disclosure has a dielectric constant greater than about 3.5. In further embodiments, the dielectric constant is greater than about 4.0, and in further specific embodiments the dielectric constant is greater than 5.0.

The addition of inorganic particles has other advantages. For example, the particles will help to hold the polymer in place during thermal curing. As a result, the layer is continuous without holes.

The dielectric layer may be any thickness suitable for use in an electronic device, such as a thin film transistor. In embodiments, the dielectric layer has a thickness of from about 50 nanometers to about 5 micrometers. In other embodiments the dielectric layer has a thickness of from about 200 nanometers to about 1 micrometer.

The dielectric layer of the present disclosure has a very smooth surface. The surface roughness of the dielectric layer is less than about 50 nanometers in some embodiments, 10 nanometers in further embodiments, and less than about 1 nanometer in still further embodiments.

The dielectric layer of the present disclosure has a hydrophobic surface. The surface properties can be characterized, for example, by measuring the water contact angle of the surface. In embodiment, the dielectric layer has a surface water contact angle larger than about 80 degrees. In further embodiments, the surface water contact angle is larger than about 90 degrees.

The dielectric layer can be applied using known methods. It is generally applied via liquid deposition such as spin coating, dip coating, blade coating, rod coating, screen printing, stamping, ink jet printing, and the like, from a composition comprising the polymer, the inorganic particle and a liquid. The polymer and inorganic particles are dissolved and/or dispersed at any suitable concentration in the liquid such as alcohol, ketone, ether, toluene, xylene, DMF, THF, and mixtures thereof, and the like. Exemplary method to prepare the composition is illustrated below. For example, polysilsesquioxanes such as poly(methyl silsequioxane) can be generated by hydrolyzing silane precursor such as methyltrimethoxysilane with water in alcohol, preferably at an acidic or basic condition. Inorganic particles, preferably nanoparticles, are subsequently added to the polysilsesquioxane solution in alcohol. Agitation such as ultrasonic vibration, mechanical milling, homogenization, and the like, is applied to above mixture to dispersion the inorganic particles. In certain embodiments, the polysilsesquioxane may react with functional groups such as hydroxyl groups at the nanoparticle surface, forming a shell layer to stabilize the nanoparticles in the composition. Filtration may be optionally conducted before deposition. After the liquid deposition, the dielectric layer is cured at a plastic compatible temperature for example less than about 200° C., or less than about 180° C. for form a robust layer.

As previously mentioned, TFTs generally comprise a supporting substrate, three electrically conductive electrodes (gate, source and drain electrodes), a channel semiconductor layer, and an electrically insulating gate dielectric layer separating the gate electrode from the semiconductor layer. The other layers and their composition/manufacture are discussed below.

The substrate in the electronic device of the present disclosure may be any suitable material including, but not limited to, silicon wafer, glass plate, a plastic film or sheet, and the like depending on the intended application. Other suitable materials include ceramic foils, coated metallic foils, acrylics, epoxies, polyamides, polycarbonates, polyimides, and polyketones. For structurally flexible electronic devices, a plastic substrate, such as, for example, polyester, polycarbonate, polyimide sheets, and the like, may be used. The thickness of the substrate may be from about 10 micrometers to over 10 millimeters, provided the required mechanical properties are satisfied for the intended application. In embodiments, the substrate is from about 50 to about 100 micrometers. In embodiments with rigid substrates, such as glass or silicon, the substrate is from about 1 to about 10 millimeters.

The gate electrode is composed of an electrically conductive material. It can be a thin metal film, a conducting polymer film, a conducting film made from conducting ink or paste or the substrate itself, for example heavily doped silicon. Examples of gate electrode materials include, but are not restricted to, aluminum, gold, chromium, indium tin oxide, conductive polymers such as polystyrene sulfonate-doped poly(3,4-ethylenedioxythiophene) (PSS-PEDOT), and conducting ink/paste comprised of carbon black/graphite. The gate electrode can be prepared by vacuum evaporation, sputtering of metals or conductive metal oxides, conventional lithography and etching, chemical vapor deposition, spin coating, casting or printing, or other deposition processes. The thickness of the gate electrode ranges from about 10 to about 500 nanometers for metal films and from about 0.5 to about 10 micrometers for conductive polymers.

The semiconductor layer generally is an organic semiconducting material. Examples of organic semiconductors include, but are not limited to, acenes, such as anthracene, tetracene, pentacene, and their substituted derivatives, perylenes, fullerenes, oligothiophenes, polythiophenes and their substituted derivatives, polypyrrole, poly-p-phenylenes, poly-p-phenylvinylidenes, naphthalenedicarboxylic dianhydrides, naphthalene-bisimides, polynaphthalenes, phthalocyanines such as copper phthalocyanines or zinc phthalocyanines and their substituted derivatives. In one exemplary embodiment, the semiconductor used is a p-type semiconductor. In another exemplary embodiment, the semiconductor is a liquid crystalline semiconductor. In another preferred embodiment, the semiconductor polymers are for examples polythiophene, triarylamine polymers, polyindolocarbazoles, and the like. Polythiophenes include, for example, both regioregular and regiorandom poly(3-alkylthiophene)s, polythiophenes comprising substituted and unsubstituted thienylene groups, polythiophenes comprising optionally substituted thieno[3,2-b]thiophene and/or optionally substituted thieno[2,3-b]thiophene groups, and polythiophenes comprising non-thiophene based aromatic groups such as phenylene, fluorene, furan, and the like. The semiconductor layer is from about 5 nm to about 1000 nm thick. The semiconductor layer can be formed by molecular beam deposition, vacuum evaporation, sublimation, spin-on coating, dip coating, blade coating,-rod coating, screen printing, stamping, ink jet printing, and the like, and other conventional processes known in the art, including those processes described in forming the gate electrode.

Typical materials suitable for use as source and drain electrodes include those of the gate electrode materials such as gold, nickel, aluminum, platinum, conducting polymers, and conducting inks. In embodiments, the conductive material provides low contact resistance to the semiconductor. Typical thicknesses are about, for example, from about 40 nanometers to about 1 micrometer with a more specific thickness being about 100 to about 400 nanometers. The TFTs of the present disclosure contain a semiconductor channel. The semiconductor channel width may be, for example, from about 10 micrometers to about 5 millimeters with a specific channel width being about 100 micrometers to about 1 millimeter. The semiconductor channel length may be, for example, from about 1 micrometer to about 1 millimeter with a more specific channel length being from about 5 micrometers to about 100 micrometers.

The source electrode is grounded and a bias voltage of, for example, about 0 volt to about 80 volts, is applied to the drain electrode to collect the charge carriers transported across the semiconductor channel when a voltage of, for example, about +10 volts to about −80 volts, is applied to the gate electrode. The electrodes may be formed or deposited using conventional processes known in the art.

The various components of the TFT may be deposited upon the substrate in any order, as is seen in the Figures. The term “upon the substrate” should not be construed as requiring that each component directly contact the substrate. The term should be construed as describing the location of a component relative to the substrate. Generally, however, the gate electrode and the semiconductor layer should both be in contact with the dielectric layer. In addition, the source and drain electrodes should both be in contact with the semiconductor layer.

The following examples illustrate TFTs made according to the methods of the present disclosure. The examples are merely illustrative and are not intended to limit the present disclosure with regard to the materials, conditions, or process parameters set forth therein. All parts are percentages by weight unless otherwise indicated.

### EXAMPLES

### Preparation of Dielectric Layer

40 g methyltrimethoxysilane (from Aldrich), 10 g de-ionized water, and 100 g n-butanol were mixed together and refluxed for 5-8 hours with rigorous stirring. Poly(methyl silsesquioxane) was formed via hydrolyzing and condensation of the methyltrimethoxysilane monomer.

0.1 g Al₂O₃ nanoparticles (from Nanophase) with particle size of about 47 nm were added into 0.9 g of the above solution. The mixture was subjected to ultrasonic for 1 hour at room temperature. A stable milk dispersion was obtained after filtration with a 1 micron glass filter.

### Measurement of Capacitance

The dispersion (described above) was deposited onto an aluminum-coated polyester substrate. A thin film was obtained by spin coating the dispersion at 1000 rpm for about 40 seconds. The thin film was first heated at 80° C. on a hotplate at ambient atmosphere for 5-10 min, then at 160° C. for 10-20 min to cure the poly(methyl silsesquioxane) resin. The resulting dielectric layer had a thickness about 950 nm and surface roughness about 16 nm as measured by a surface profile-meter.

A gold electrode layer was vacuum deposited on top of the dielectric layer. The capacitance was measured at 3.3 nF/cm² with a capacitor meter and the calculated dielectric constant was 3.6. This dielectric constant is higher than that of methyl silsesquioxane resin (˜2.9), suggesting that the increase in dielectric constant came from the added Al₂O₃ nanoparticles.

### Fabrication and Characterization of TFT

A thin film transistor was made with a dielectric layer as described above. The dispersion (described above) was deposited onto an aluminum-coated polyester substrate. A thin film was obtained by spin coating the dispersion at 1000 rpm for about 40 seconds. The thin film was first heated at 80° C. on a hotplate at ambient atmosphere for 5-10 min, then at 160° C. for 10-20 min to cure the poly(methyl silsesquioxane) resin. The polythiophene PQT-12, as disclosed in B. Ong et al, J. Am. Chem. Soc., 2004, 126(11):3378-79, was deposited by spin coating at a speed of 1000 rpm for 120 seconds, dried in a vacuum oven, and then heated at 140° C. for 10-30 minutes. A series of source electrode and drain electrode pairs were vacuum deposited on top of the semiconductor layer through a shadow mask, thus forming a set of TFTs of various dimensions.

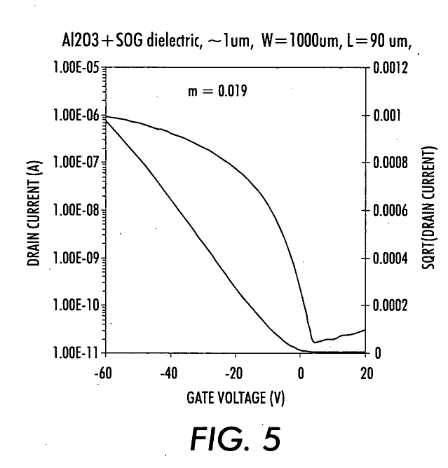

The devices were evaluated using a Keithley 4200 TFT characterization instrument. FIG. 5 shows typical output and transfer curves of a transistor with channel length of 90 microns and channel width of 1000 microns. The device was turned on nicely at around zero voltage with a very good current on/off ratio of 44,000. Mobility was calculated to be 0.02 cm²/V·sec.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. An electronic device having a dielectric layer which comprises:
a polymer selected from the group consisting of polysiloxane, polysilsesquioxane, and mixtures thereof; and
inorganic particles.

2. The electronic device of claim 1, wherein the electronic device is a thin film transistor.

3. The thin film transistor of claim 2, wherein the polysiloxane has the chemical structure of Formula (I): 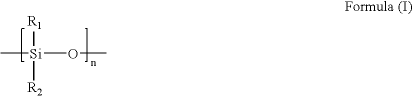
wherein R₁ and R₂ are independently selected from alkyl, alkenyl, aryl, arylalkyl, and hydrogen; wherein R₁ and R₂ may further contain a heteroatom selected from the group consisting of oxygen, sulfur, and nitrogen; and wherein n is the degree of polymerization.

4. The thin film transistor of claim 3, wherein n is from about 4 to about 10,000.

5. The thin film transistor of claim 2, wherein the polysilsesquioxane has the chemical structure of Formula (II):
(SiR)₂ₙO₃ₙ (II)
wherein Rs are the same or different from each other, and wherein the Rs are independently selected from alkyl, alkenyl, aryl, arylalkyl, and hydrogen; wherein the Rs may further contain a heteroatom selected from the group consisting of oxygen, sulfur, and nitrogen; and wherein n is the degree of polymerization.

6. The thin film transistor of claim 5, wherein n is from about 2 to about 10,000.

7. The thin film transistor of claim 5, wherein the polymer is poly(methyl silsesquioxane).

8. The thin film transistor of claim 2, wherein the dielectric layer has a thickness of from about 50 nanometers to about 5 micrometers.

9. The thin film transistor of claim 2, wherein the inorganic particles are selected from the group consisting of A₂O₃, ZrSiO₄, Si₃N₄, SrO, MgO, CaO, HfSiO₄, BaTiO₃, TiO₂, ZrO₂, La₂O₃, Y₂O₃, Ta₂O₅, HfO₂, and mixtures thereof.

10. The thin film transistor of claim 2, wherein the inorganic particles have an average particle size of from about 1 nanometer to about 999 nanometers.

11. The thin film transistor of claim 10, wherein the inorganic particles have an average particle size of from about 1 nanometer to about 100 nanometers.

12. The thin film transistor of claim 2, wherein the weight ratio of polymer to inorganic particles is from about 1:1 to about 19:1.

13. The thin film transistor of claim 12, wherein the weight ratio of polymer to inorganic particles is from about 4:1 to about 19:1.

14. The thin film transistor of claim 2, wherein the dielectric layer has a surface roughness of less than about 50 nanometers.

15. The thin film transistor of claim 2, wherein the dielectric layer has a dielectric constant greater than about 3.5.

16. The thin film transistor of claim 2, further comprising a polythiophene semiconductor layer.

17. A thin film transistor having a dielectric layer comprising a poly(methyl silsesquioxane) polymer and Al₂O₃ nanoparticles, the dielectric layer having a dielectric constant greater than about 3.5.

18. A process for fabricating a thin film transistor comprising:
depositing a dielectric layer upon a substrate;
wherein the dielectric layer comprises a polymer selected from the group consisting of polysiloxane, polysilsesquioxane, and mixtures thereof; and inorganic particles.

19. The process of claim 18, wherein the particles are nanoparticles of a material selected from the group consisting of Al₂O₃, ZrSiO₄, Si₃N₄, SrO, MgO, CaO, HfSiO₄, BaTiO₃, TiO₂, La₂O₃, Y₂O₃, Ta₂O₅, HfO₂, ZrO₂, and mixtures thereof.

20. The process of claim 18, wherein the polymer is poly(methyl silsesquioxane) and the particles are Al₂O₃ nanoparticles.
